(19) United States
(12) Patent Application Publication
(10) Pub. No.: US 2013/0099180 A1
(43) Pub. Date: Apr. 25, 2013

(54) USE OF ALKALINE-EARTH METALS TO REDUCE IMPURITY INCORPORATION INTO A GROUP-III NITRIDE CRYSTAL GROWN USING THE AMMONOTHERMAL METHOD

(71) Applicant: The Regents of the University of California, Oakland, CA (US)

(72) Inventors: Siddha Pimputkar, Santa Barbara, CA (US); Paul M. von Dollen, Santa Barbara, CA (US); James S. Speck, Goleta, CA (US); Shuji Nakamura, Santa Barbara, CA (US)

(73) Assignee: The Regents of the University of California, Oakland, CA (US)

(21) Appl. No.: 13/659,389

(22) Filed: Oct. 24, 2012

Related U.S. Application Data
(60) Provisional application No. 61/550,742, filed on Oct. 24, 2011.

(51) Int. Cl. C30B 7/10

(52) U.S. Cl. CPC C30B 7/105
USPC 252/519.14; 117/71; 117/224

(57) ABSTRACT

Alkaline-earth metals are used to reduce impurity incorporation into a Group-III nitride crystal grown using the ammonothermal method.

### CROSS REFERENCE TO RELATED APPLICATIONS

This application claims the benefit under 35 U.S.C. Section 119(e) of U.S. Provisional Application Ser. No. 61/550,742, filed on Oct. 24, 2011, by Siddha Pimputkar, Paul von Dollen, James S. Speck, and Shuji Nakamura, and entitled “USE OF ALKALINE-EARTH METALS TO REDUCE IMPURITY INCORPORATION INTO A GROUP-III NITRIDE CRYSTAL GROWN USING THE AMMONOTHERMAL METHOD,” attorneys' docket number 30794.433-US-P1 (2012-236-1), which application is hereby incorporated by reference herein.

This application is related to the following co-pending and commonly-assigned application:

U.S. patent application Ser. No. 13/128,092, filed on May 6, 2011, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys' docket number 30794.300-US-WO (2009-288-2), which application claims the benefit under 35 U.S.C. Section 365(c) of P.C.T. International Patent Application Serial No. PCT/US2009/063233, filed on Nov. 4, 2009, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys' docket number 30794.300-WO-U1 (2009-288-2), which application claims the benefit under 35 U.S.C. Section 119(e) of U.S. Provisional Application Ser. No. 61/112,550, filed on Nov. 7, 2008, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorney's docket number 30794.300-US-P1 (2009-288-1);

U.S. Patent Application Serial No. 13/549,188, filed on Jul. 13, 2012, by Siddha Pimputkar and James S. Speck, entitled “GROWTH OF BULK GROUP-III NITRIDE CRYSTALS AFTER COATING THEM WITH A GROUP-III METAL AND AN ALKALI METAL,” attorneys' docket number 30794.420-US-U1 (2012-021-2), which application claims the benefit under 35 U.S.C. Section 119(e) of U.S. Provisional Application Ser. No. 61/507,182, filed on Jul. 13, 2011, by Siddha Pimputkar and James S. Speck, entitled “GROWTH OF BULK GROUP-III NITRIDE CRYSTALS AFTER COATING THEM WITH A GROUP-III METAL AND AN ALKALI METAL,” attorney's docket number 30794.420-US-P1 (2012-021-1); and

P.C.T. International Patent Application Serial No. PCT/US2012/046761, filed on Jul. 13, 2012, by Siddha Pimputkar, Shuji Nakamura and James S. Speck and, entitled “METHOD FOR IMPROVING THE TRANSPARENCY AND QUALITY OF GROUP-III NITRIDE CRYSTALS AMMONOTHERMALLY GROWN IN A HIGH PURITY GROWTH ENVIRONMENT,” attorneys' docket number 30794.422-WO-U1 (2012-023-2), which application claims the benefit under 35 U.S.C. Section 119(e) of U.S. Provisional Application Ser. No. 61/507,212, filed on Jul. 13, 2011, by Siddha Pimputkar, Shuji Nakamura and James S. Speck, entitled “HIGHER PURITY GROWTH ENVIRONMENT FOR THE AMMONTHERMAL GROWTH OF GROUP-III NITRIDES,” attorney's docket number 30794.422-US-P1 (2012-023-1); all of which applications are incorporated by reference herein.

### BACKGROUND OF THE INVENTION

1. Field of the Invention

The invention is related generally to the field of Group-III nitride semiconductors, and more particularly, to the use of alkaline-earth metals to reduce impurity incorporation into a Group-III nitride crystal grown using the ammonothermal method.

2. Description of the Related Art

Ammonothermal growth of Group-III nitrides, for example GaN, involves placing within a vessel Group-III containing source material, Group-III nitride seed crystals, and a nitrogen-containing fluid or gas, such as ammonia, sealing it and heating it to conditions such that the reactor is at elevated temperatures (between 23° C. and 1000° C.) and high pressures (between 1 atm and, for example, 30,000 atm). Under these temperatures and pressures, the nitrogen-containing fluid becomes a supercritical fluid and normally exhibits enhanced solubility of Group-III nitride material. The solubility of Group-III nitride into the nitrogen-containing fluid is dependent on the temperature, pressure and density of the fluid, among other things.

By creating two different zones within the vessel, it is possible to establish a solubility gradient where in one zone the solubility will be higher than in a second zone. The source material is then preferentially placed in the higher solubility zone and the seed crystals in the lower solubility zone. By establishing fluid motion between these two zones, for example, by making use of natural convection, it is possible to transport Group-III nitride material from the higher solubility zone to the lower solubility zone where it then deposits itself onto the seed crystals.

During the growth of the Group-III nitride crystals, it is imperative that the concentrations of impurities within the closed vessel are reduced to a minimum before and during growth. One method to reduce impurities within the vessel includes lining the vessel walls with high purity liner materials. While this is effective, impurities, such as oxygen and water, may adhere to the surfaces of vessel walls and material placed inside the vessel (such as the seed crystals and source material along with the structural components used to place the different material into different zones of the vessel, such as the source basket) and incorporate into the solvent once the vessel is heated to elevated temperatures.

Furthermore, impurities may be present within the materials used as a source for the Group-III crystal. For example, poly-crystalline GaN can be used as a source material for the growth of single crystal GaN crystals. The source material, though, depending on the production method, may contain considerable amounts of oxygen (>1E19 oxygen atoms/cm³), which are released continuously during growth by means of dissolution. Therefore, while it is possible to remove surface contaminations through other means, such as baking and purging the system, selective removal of material during growth is an important aspect of maintaining purity.

While it may be beneficial to reduce the overall concentration of impurities within the fluid, it may be necessary to maintain a certain concentration to enable or facilitate certain chemical reactions. Therefore, in order to benefit the growth of the crystal, it may be necessary to maintain a higher concentration of material within the fluid, although it is preferred not to incorporate these impurities into the crystal during growth.

As an example, for the basic ammonothermal growth of a Group-III nitride, such as GaN, it is beneficial to include sodium to the growth environment. The sodium enhances the amount of Ga and/or GaN that can be dissolved into the supercritical solution. Typically, it is desirable to have the highest possible amount of dissolved Ga and/or GaN for the growth of GaN as this typically enhances growth rates and improves the quality of the growth crystal. Nonetheless, while sodium enhances the growth rate, it is an undesirable element within the crystal as it modifies the optical, structural, and electric properties of the GaN crystal.

Therefore, there is a need in the art for improved methods of reducing impurity incorporation during the growth of Group-III nitride crystals under ammonothermal growth. The present invention satisfies this need.

### SUMMARY OF THE INVENTION

To overcome the limitations in the prior art described above, and to overcome other limitations that will become apparent upon reading and understanding the present specification, the present invention discloses the use of alkaline-earth metals to reduce impurity incorporation into a Group-III nitride crystal grown using the ammonothermal method.

### BRIEF DESCRIPTION OF THE DRAWINGS

Referring now to the drawings in which like reference numbers represent corresponding parts throughout:

FIG. 1 is a schematic of a high-pressure vessel according to an embodiment of the present invention.

FIG. 2 is a flowchart illustrating the method according to an embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Overview

The addition of one or more alkaline-earth metals or alkaline-earth metal containing compounds or alloys to the ammonothermal growth environment during the growth of a Group-III nitride crystal lowers the incorporation of impurities into the growing crystal and/or lowers the concentration of active impurities within the growth environment.

Specifically, the present invention envisions the use of alkaline-earth metal containing materials as either an impurity getter and/or for surface related effects (such as, but not limited to, surfactant effects, or the formation of a passivation layer) to prevent the incorporation of the impurity into the crystal during growth. In particular, this invention includes the use of alkaline-earth metals to remove oxygen from the growth environment and/or to prevent the incorporation of the oxygen into the crystal.

As a result, the present invention may be used with bulk GaN substrates for use in electronic or optoelectronic devices, in order to provide higher purity GaN substrates, including better optical transparency due to reduced impurity uptake. Experimental data showed consistent lowering of oxygen concentrations in bulk GaN crystals using the present invention. Further efforts will further expand on existing results to verify reproducibility and reliability of method. Future plans include the further development and improvement of existing experimental results and setup.

### Apparatus Description

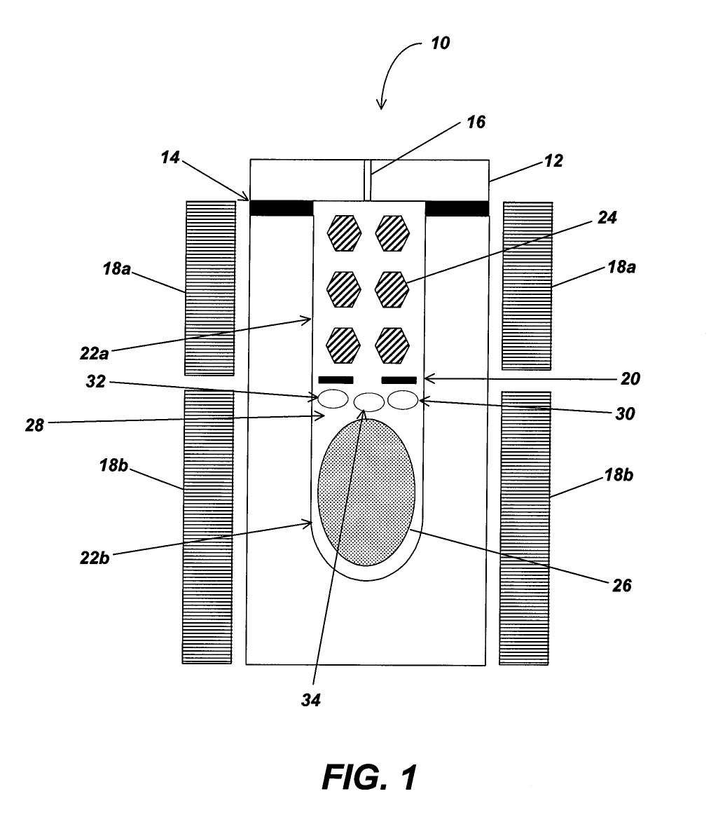

FIG. 1 is a schematic of an ammonothermal growth system comprising a high-pressure reaction vessel 10 according to one embodiment of the present invention. The vessel, which is an autoclave, may include a lid 12, gasket 14, inlet and outlet port 16, and external heaters/coolers 18a and 18b. A baffle plate 20 divides the interior of the vessel 10 into two zones 22a and 22b, wherein the zones 22a and 22b are separately heated and/or cooled by the external heaters/coolers 18a and 18b, respectively. An upper zone 22a may contain one or more Group-III nitride seed crystals 24 and a lower zone 22b may contain one or more Group-III containing source materials 26, although these positions may be reversed in other embodiments. Both the seed crystals 24 and source materials 26 may be contained within baskets or other containment devices, which are typically comprised of a Ni—Cr alloy. The vessel 10 and lid 12, as well as other components, may also be made of a Ni—Cr based alloy.

Finally, the interior of the vessel 10 is filled with a nitrogen-containing solvent 28 to accomplish the ammonothermal growth. Preferably, the nitrogen-containing solvent 28 contains at least 1% ammonia.

Moreover, the solvent 28 may also contain one or more alkaline-earth containing materials 30, namely alkaline-earth metals. The alkaline-earth containing material 30 is used as an “impurities getter” for binding to one or more impurities 32 present in the vessel 10. The result of this binding is an impurity compound 34 comprised of both the alkaline-earth containing material 30 and one or more of the impurities 32. The alkaline-earth containing material 30, impurities 32 and impurities compound 34 may exist in any state, i.e., supercritical, gas, liquid or solid.

In one embodiment, the alkaline-earth containing materials 30 may include: metallic beryllium, metallic magnesium, metallic calcium, metallic strontium, beryllium nitride, magnesium nitride, calcium nitride, strontium nitride, beryllium hydride, magnesium hydride, calcium hydride, strontium hydride, beryllium amide, magnesium amide, calcium amide, or strontium amide.

Moreover, in one embodiment, the impurities 32 may comprise one or more alkali metals. For example, there may be a need to allow the presence of sodium within the growth environment, yet prevent the sodium from incorporating into a GaN crystal. Nonetheless, while this example includes sodium and the growth of GaN, it should not be considered restricting in any sense, and the present invention applies towards other materials that do not make up the desired elements of the Group-III nitride, such as alkali metals, alkaline earth metals, halogens, etc. In another example, the impurities 32 may include oxygen, water, oxygen-containing compounds or any other materials in the vessel.

### Process Description

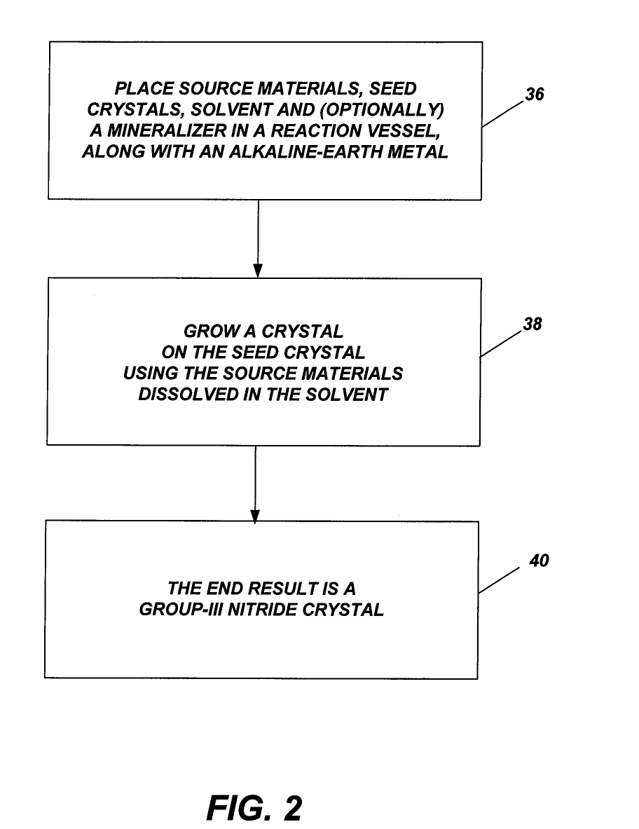

FIG. 2 is a flow chart illustrating a method for obtaining or growing a Group-III nitride-containing crystal using the apparatus of FIG. 1 according to one embodiment of the present invention.

Block 36 represents placing one or more Group-III nitride seed crystals 24, one or more Group-III containing source materials 26, and a nitrogen-containing solvent 28 in the vessel 10, wherein the seed crystals 24 are placed in a seed crystals zone (i.e., either 22a or 22b, namely opposite the zone 22b or 22a containing the Group-III containing source materials 26), the source materials 26 are placed in a source materials zone (i.e., either 22b or 22a, namely opposite the zone 22a or 22b containing the seed crystals 24). The seed crystals 24 may comprise any quasi-single Group-III containing crystal; the source materials 26 may comprise a Group-III containing compound, a Group-III element in its pure elemental form, or a mixture thereof, i.e., a Group-III nitride monocrystal, a Group-III nitride polycrystal, a Group-III nitride powder, Group-III nitride granules, or other Group-III containing compound; and the solvent 28 may comprise supercritical ammonia or one or more of its derivatives, which may be entirely or partially in a supercritical state. An optional mineralizer may be placed in the vessel 10 as well, wherein the mineralizer increases the solubility of the source materials 26 in the solvent 28 as compared to the solvent 28 without the mineralizer.

Block 38 represents growing Group-III nitride crystal on one or more surfaces of the seed crystals 24, wherein the environments and/or conditions for growth include forming a temperature gradient between the seed crystals 24 and the source materials 26 that causes a higher solubility of the source materials 26 in the solvent 28 in the source materials zone and a lower solubility, as compared to the higher solubility, of the source materials 26 in the solvent 28 in the seed crystals zone. Specifically, growing the Group-III nitride crystals on one or more surfaces of the seed crystals 24 occurs by changing the source materials zone temperatures and the seed crystals zone temperatures to create a temperature gradient between the source materials zone and the seed crystals zone that produces a higher solubility of the source materials 26 in the solvent 28 in the source materials zone as compared to the seed crystals zone. For example, the source materials zone and seed crystals zone temperatures may range between 0° C. and 1000° C., and the temperature gradients may range between 0° C. and 1000° C.

Block 40 comprises the resulting product created by the process, namely, a Group-III nitride crystal grown by the method described above. A Group-III nitride substrate may be created from the Group-III nitride crystal, and a device may be created using the Group-III nitride substrate.

### Use of Alkaline-Earth Materials During Ammonothermal Growth

The present invention envisions using alkaline-earth containing materials 30 within the vessel 10 of FIG. 1 during the process steps of FIG. 2 to modify the vessel's environment. Specifically, the alkaline-earth containing materials 30 are placed into the vessel in Block 36 for use as impurity getters for binding to the impurities 32 during the ammonothermal growth of Group-III nitride crystals 40 in Block 38, resulting in impurities compounds 34 that may be removed from the vessel 10 before, during or after the ammonothermal growth of Group-III nitride crystals 40. The result is that Group-III nitride crystals 40 grown using the alkaline-earth containing materials 30 have fewer impurities as compared to Group-III nitride crystals 40 grown without the alkaline-earth containing materials 30. In addition, the alkaline-earth containing materials 30 may be used to modify or enhance the solubility of source materials 26 and the seed crystals 24 into the solvent 28.

### Experimental Data

Experimental data revealed the following.

An ammonothermal growth was performed on three different seed crystals. Each seed crystal comprised a GaN substrate which was sliced from a GaN boule grown by Hydride Vapor Phase Epitaxy (HVPE), and polished to provide an atomically flat surface. The primary facet which is exposed during the growth corresponds to the crystallographic plane which is parallel to the substrate surface.

For this experiment, three different seeds where used: m-plane with a two degree off-orientation towards the (0001) c-plane (designated as nonpolar (10-10) c+2), as well as semipolar (11-22), and polar (0001) c-plane.

The growth was performed in a Ni—Cr superalloy vessel, and entailed loading the reactor with these three seeds, baffle plates to control the fluid motion, and source material comprising poly-crystalline material created as a by-product from the HVPE process. The oxygen concentration in the source material typically ranges between 1E19 oxygen atoms/cm³ and 5E19 oxygen atoms/cm³.

The vessel was then filled with sodium metal, calcium nitride, and ammonia.

Having sealed the vessel, it was then subject to a temperature gradient across the source material and the seed crystals, allowing the seed crystal to grow.

After a 5 day growth, the vessel was opened and the crystals removed.

To determine the impurity concentration, particularly oxygen, a SIMS (Secondary Ion Mass Spectrometry) analysis was performed on the primary facet. The following table summarizes the results for oxygen impurities provided as oxygen atoms per cubic centimeter of GaN crystal and is compared to typical results for the same seed crystal orientations without the addition of an alkaline-earth metal impurity getter.

| Initial Primary | | With Alkaline- | |
|---|---|---|---|
| Seed Crystal | Typical | Earth Getter | |
| Facet | [atoms/cm³] | [atoms/cm³] | Reduction |
| (0001) | 1 × 10¹⁹ | 1 × 10¹⁹ | same |
| (000-1) | 5 × 10¹⁹ | 1 × 10¹⁹ | 5× |
| (10-10) c + 2 | 5 × 10¹⁹ | 8 × 10¹⁸ | 6× |
| (11-22) | 2 × 10²⁰ | 2 × 10¹⁹ | 10× |

Based on a single growth run, typical oxygen impurities levels have been reduced to a low 10¹⁹ or below. Further refinement is expected to yield better results.

### Nomenclature

The terms “III-nitride,” “Group-III nitride”, or “nitride,” as used herein refer to any alloy composition of the (B,Al,Ga,In)N semiconductors having the formula B_{z}Al_{y}Ga_{1-y-x-z}InₓN, wherein 0<=x<=1, 0<=y<=1, 0<=z<=1. These terms are intended to be broadly construed to include respective nitrides of the single species, B, Al, Ga, and In, as well as binary, ternary and quaternary compositions of such Group-III metal species. Accordingly, it will be appreciated that the discussion of the invention hereinafter in reference to GaN and InGaN materials is applicable to the formation of various other (B,Al,Ga,In)N material species. Further, (B,Al,Ga,In)N materials within the scope of the invention may further include minor quantities of dopants and/or other impurity or inclusional materials.

Many (B,Al,Ga,In)N devices are grown along the polar c-plane of the crystal, although this results in an undesirable quantum-confined Stark effect (QCSE), due to the existence of strong piezoelectric and spontaneous polarizations. One approach to decreasing polarization effects in (B,Al,Ga,In)N devices is to grow the devices on nonpolar or semipolar planes of the crystal.

The term “nonpolar plane” includes the {11-20} planes, known collectively as a-planes, and the {10-10} planes, known collectively as m-planes. Such planes contain equal numbers of gallium and nitrogen atoms per plane and are charge-neutral. Subsequent nonpolar layers are equivalent to one another, so the bulk crystal will not be polarized along the growth direction.

The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

Miller indices are a notation system in crystallography for planes and directions in crystal lattices, wherein the notation {h, i, k, l} denotes the set of all planes that are equivalent to (h, i, k, 1) by the symmetry of the lattice. The use of braces, { }, denotes a family of symmetry-equivalent planes represented by parentheses, ( ) wherein all planes within a family are equivalent for the purposes of this invention.

### Conclusion

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for growing crystals, comprising:
(a) placing source materials and one or more seeds into a vessel;
(b) filling the vessel with a solvent for dissolving the source materials and transporting the dissolved source materials to the seeds for growth of the crystals; and
(c) using alkaline-earth containing materials in the vessel to reduce impurity incorporation into the crystals.

2. The method of claim 1, wherein the source materials comprise Group-III containing source materials, the seeds comprise any quasi-single crystals, the solvent comprises a nitrogen-containing solvent, and the crystals comprise Group-III nitride crystals.

3. The method of claim 1, wherein the impurities are oxygen-containing materials in the vessel.

4. The method of claim 1, wherein the impurities are one or more alkali metals.

5. The method of claim 1, wherein the alkaline-earth containing materials are used to modify or enhance solubility of the source materials or seeds into the solvent.

6. The method of claim 1, wherein the alkaline-earth containing materials comprise: metallic beryllium, metallic magnesium, metallic calcium, metallic strontium, beryllium nitride, magnesium nitride, calcium nitride, strontium nitride, beryllium hydride, magnesium hydride, calcium hydride, strontium hydride, beryllium amide, magnesium amide, calcium amide, or strontium amide.

7. A crystal grown by the method of claim 1.

8. An apparatus for growing crystals, comprising:
(a) a vessel for containing source materials and seeds,
(b) wherein the vessel is filled with a solvent for dissolving the source materials and the dissolved source materials are transported to the seeds for growth of the crystals; and
(c) wherein alkaline-earth containing materials are used in the vessel to reduce impurity incorporation into the crystals.

9. The apparatus of claim 8, wherein the source materials comprise Group-III containing source materials, the seed crystals comprise any quasi-single crystals, the solvent comprises a nitrogen-containing solvent, and the crystals comprise Group-III nitride crystals.

10. The apparatus of claim 8, wherein the impurities are oxygen-containing materials in the vessel.

11. The apparatus of claim 8, wherein the impurities are one or more alkali metals.

12. The apparatus of claim 8, wherein the alkaline-earth containing materials are used to modify or enhance solubility of the source materials or seeds into the solvent.

13. The apparatus of claim 8, wherein the alkaline-earth containing materials comprise: metallic beryllium, metallic magnesium, metallic calcium, metallic strontium, beryllium nitride, magnesium nitride, calcium nitride, strontium nitride, beryllium hydride, magnesium hydride, calcium hydride, strontium hydride, beryllium amide, magnesium amide, calcium amide, or strontium amide.
